(19) United States
(12) Patent Application Publication
(10) Pub. No.: US 2026/0255756 A1
(43) Pub. Date: Aug. 27, 2026

(54) DISPLAY DEVICE AND ELECTRONIC DEVICE INCLUDING THE SAME

(71) Applicant: Samsung Display Co., Ltd., Yongin-si (KR)

(72) Inventors: SI JOON SONG, Yongin-si (KR); DONGHYUN LEE, Yongin-si (KR); GICHANG LEE, Yongin-si (KR)

(21) Appl. No.: 19/453,753

(22) Filed: Jan. 20, 2026

(30) Foreign Application Priority Data
Feb. 27, 2025 (KR) 10-2025-0026173

(51) Int. Cl. H10H 29/49; H10H 29/41; H10H 29/85

(52) U.S. Cl. CPC H10H 29/49; H10H 29/41; H10H 29/8508

(57) ABSTRACT

A display device includes: a display panel including a first pad; an encapsulation substrate facing the display panel, the encapsulation substrate including: a glass substrate; at least one insulating layer on one surface of the glass substrate; a signal line on the one surface of the glass substrate; and a second pad electrically connected to the signal line and corresponding to the first pad; and an anisotropic conductive adhesive layer having a closed-line shape, the anisotropic conductive adhesive layer being between the display panel and the encapsulation substrate to couple the display panel and the encapsulation substrate and configured to electrically connect the first pad and the second pad, wherein the display panel includes: a semiconductor substrate; a wiring layer on the semiconductor substrate and comprising the first pad; and a light emitting element on the wiring layer.

### CROSS-REFERENCE TO RELATED APPLICATION

The present application claims priority to and the benefit of Korean Patent Application No. 10-2025-0026173, filed on February 27, 2025, in the Korean Intellectual Property Office, the entire disclosure of which is incorporated herein by reference.

### BACKGROUND

Aspects of some embodiments of the present disclosure described herein relate to a display device and an electronic device including the same.

Electronic devices, such as smart phones, notebook computers, car navigation devices, and smart televisions, which display images to users may include a display device for displaying images. Display devices may include wearable devices such as virtual reality (VR) devices, augmented reality (AR) devices, and smart watches. To display high-resolution images, wearable devices may include a light emitting diode on silicon (LEDoS) or an organic light emitting diode on silicon (OLEDoS) including a silicon substrate and a light emitting element located on the silicon substrate.

In a packaging process of a display device, a display panel and an encapsulation substrate may be bonded by an anisotropic conductive film (ACF) and may be sealed through a frit. As the bonding process and the sealing process are performed, non-uniform curing may occur. In addition, considering the width of the frit in the sealing process, it may be desirable to secure a sufficient border area of the display panel.

The above information disclosed in this Background section is only for enhancement of understanding of the background and therefore the information discussed in this Background section does not necessarily constitute prior art.

### SUMMARY

Aspects of some embodiments of the present disclosure described herein relate to a display device and an electronic device including the same, and for example, to a display device including a semiconductor substrate and an electronic device including the display device.

Aspects of some embodiments of the present disclosure include a display device that may be capable of relatively improving curing performance between a display panel and an encapsulation substrate and reducing a border area.

Aspects of some embodiments of the present disclosure include an electronic device including the display device described above.

According to some embodiments, a display device includes a display panel including a first pad, an encapsulation substrate that faces the display panel, and an anisotropic conductive adhesive layer having a closed-line shape. According to some embodiments, the encapsulation substrate includes a glass substrate, at least one insulating layer on one surface of the glass substrate, a signal line on the one surface of the glass substrate, and a second pad electrically connected to the signal line and corresponding to the first pad. According to some embodiments, the anisotropic conductive adhesive layer having the closed-line shape is between the display panel and the encapsulation substrate to couple the display panel and the encapsulation substrate and electrically connects the first pad and the second pad. According to some embodiments, the display panel includes a semiconductor substrate, a wiring layer on the semiconductor substrate and including the first pad, and a light emitting element on the wiring layer.

According to some embodiments, the second pad may include a plurality of conductive patterns and a plurality of insulating patterns, the plurality of insulating patterns and the plurality of conductive patterns may be alternately stacked, and neighboring conductive patterns among the plurality of conductive patterns may make contact with each other.

According to some embodiments, the second pad may include a first insulating pattern that overlaps an end portion of the signal line, a first conductive pattern electrically connected to the end portion of the signal line, a second insulating pattern that overlaps the first insulating pattern and that is on the first conductive pattern, a second conductive pattern on the first conductive pattern and electrically connected to the first conductive pattern, a third insulating pattern that overlaps the second insulating pattern and that is on the second conductive pattern, and a third conductive pattern on the second conductive pattern and electrically connected to the second conductive pattern.

According to some embodiments, the at least one insulating layer may include a first insulating layer, a second insulating layer, and a third insulating layer, and the second pad may include a first conductive pattern electrically connected to an end portion of the signal line through a first contact hole that penetrates the first insulating layer, a second conductive pattern electrically connected to the first conductive pattern through a second contact hole that penetrates the second insulating layer on the first insulating layer, and a third conductive pattern electrically connected to the second conductive pattern through a third contact hole that penetrates the third insulating layer on the second insulating layer.

According to some embodiments, a maximum thickness of the second pad may range from 4 μm to 7 μm.

According to some embodiments, the anisotropic conductive adhesive layer may include a photocurable resin and conductive balls mixed in the photocurable resin.

According to some embodiments, the photocurable resin may be cured at 120°C or less.

According to some embodiments, an area of the encapsulation substrate may be a larger than an area of the semiconductor substrate in a plan view.

According to some embodiments, the display panel may include a display area where the light emitting element is located and a non-display area around the display area, and a width of the non-display area may be greater than or equal to 400 μm and less than 600 μm.

According to some embodiments, the display device may further include a filling layer between the display panel and the encapsulation substrate, and the filling layer may be inside the anisotropic conductive adhesive layer.

According to some embodiments, the encapsulation substrate may include, on a lower surface thereof, a recess that corresponds to the display panel and faces toward an upper surface of the encapsulation substrate, and the filling layer may be in the recess.

According to some embodiments, a frit that couples the display panel and the encapsulation substrate may not be included inside or outside the anisotropic conductive adhesive layer.

According to some embodiments, an electronic device includes a display panel including a first pad, an encapsulation substrate that faces the display panel, a timing controller on the encapsulation substrate, and an anisotropic conductive adhesive layer having a closed-line shape. According to some embodiments, the encapsulation substrate includes a glass substrate, at least one insulating layer on one surface of the glass substrate, a signal line on the one surface of the glass substrate, and a second pad electrically connected to the signal line and corresponding to the first pad. According to some embodiments, the anisotropic conductive adhesive layer having the closed-line shape is between the display panel and the encapsulation substrate to couple the display panel and the encapsulation substrate and electrically connects the first pad and the second pad. According to some embodiments, the display panel includes a semiconductor substrate, a wiring layer on the semiconductor substrate and including the first pad, and a light emitting element on the wiring layer.

According to some embodiments, the electronic device may further include a flexible circuit board electrically connected with the timing controller, and the timing controller and the flexible circuit board may be electrically connected through wiring of the encapsulation substrate.

According to some embodiments, the electronic device may further include a source driver chip on the one surface of the glass substrate, and the display panel may further include a third pad and a scan line electrically connected to the third pad. According to some embodiments, the encapsulation substrate may further include a sub-signal line on the one surface of the glass substrate and electrically connected with the source driver chip and a fourth pad electrically connected to the sub-signal line, and the third pad and the fourth pad may be electrically connected through the anisotropic conductive adhesive layer.

According to some embodiments, the second pad may include a plurality of conductive patterns and a plurality of insulating patterns, the plurality of insulating patterns and the plurality of conductive patterns may be alternately stacked, and neighboring conductive patterns among the plurality of conductive patterns may make contact with each other.

According to some embodiments, the second pad may include a first insulating pattern that overlaps an end portion of the signal line, a first conductive pattern electrically connected to the end portion of the signal line, a second insulating pattern that overlaps the first insulating pattern and that is on the first conductive pattern, a second conductive pattern on the first conductive pattern and electrically connected to the first conductive pattern, a third insulating pattern that overlaps the second insulating pattern and that is on the second conductive pattern, and a third conductive pattern on the second conductive pattern and electrically connected to the second conductive pattern.

According to some embodiments, a maximum thickness of the second pad may range from 4 μm to 7 μm.

According to some embodiments, the display panel may include a display area where the light emitting element is located and a non-display area around the display area, and a width of the non-display area may be greater than or equal to 400 μm and less than 600 μm.

According to some embodiments, the anisotropic conductive adhesive layer may include a photocurable resin and conductive balls mixed in the photocurable resin.

### BRIEF DESCRIPTION OF THE DRAWINGS

The above and other aspects and features of embodiments according to the present disclosure will become more apparent by describing in more detail aspects of some embodiments thereof with reference to the accompanying drawings.

FIG. 1 is a block diagram of an electronic device according to some embodiments.

FIG. 2 illustrates schematic views of electronic devices according to some embodiments.

FIG. 3 is an exploded perspective view of the electronic device according to some embodiments.

FIG. 4 is a perspective view of a display panel according to some embodiments.

FIG. 5 is a schematic sectional view of the display panel according to some embodiments.

FIG. 6 is a sectional view of the display panel according to some embodiments.

FIG. 7 is a schematic plan view of the electronic device according to some embodiments.

FIG. 8 is a schematic sectional view of the electronic device according to some embodiments.

FIG. 9A is an enlarged plan view of a pad area according to some embodiments.

FIG. 9B is a sectional view of an encapsulation substrate according to some embodiments.

FIG. 9C is a sectional view illustrating a shape in which the encapsulation substrate and the display panel are coupled according to some embodiments.

FIG. 10 is a sectional view of the encapsulation substrate corresponding to the line III-III’ of FIG. 7.

FIG. 11 is a sectional view of the electronic device corresponding to the line IV-IV’ of FIG. 7.

FIG. 12A is an enlarged plan view of a pad area according to some embodiments.

FIG. 12B is a sectional view of an encapsulation substrate according to some embodiments.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component, part, area, layer, or portion from other components, parts, areas, layers, or portions. For example, without departing the scope and scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

A display device according to some embodiments may be applied to various electronic devices. An electronic device according to some embodiments may include the above-described display device and may further include modules or devices having other additional functions, in addition to the display device.

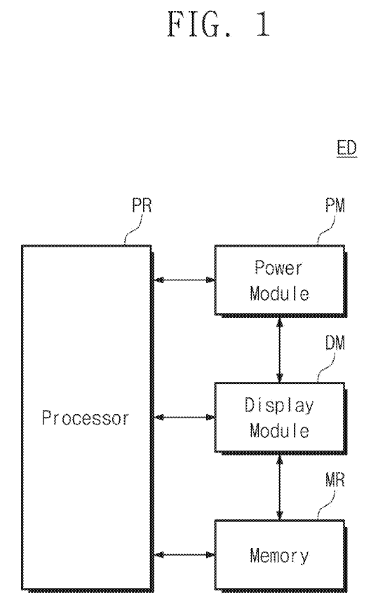

FIG. 1 is a block diagram of an electronic device ED according to some embodiments. Referring to FIG. 1, the electronic device ED according to some embodiments may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), and a controller.

Data information required for operation of the processor PR or the display module DM may be stored in the memory MR. When the processor PR executes an application stored in the memory MR, an image data signal and/or an input control signal may be transferred to the display module DM, and the display module DM may process the provided signal and may output image information through a display screen.

The power module PM may include a power supply module such as a power adaptor or a battery device and a power conversion module that converts power supplied by the power supply module and generates power required for operation of the electronic device ED.

At least one of the components6 of the electronic device ED described above may be included in the display device according to some embodiments described above. In addition, some of the separate modules functionally included in one module may be included in the display device, and the others may be provided separately from the display device. For example, the display device may include the display module DM, and the processor PR, the memory MR, and the power module PM may be provided in the form of other devices in the electronic device ED rather than the display device.

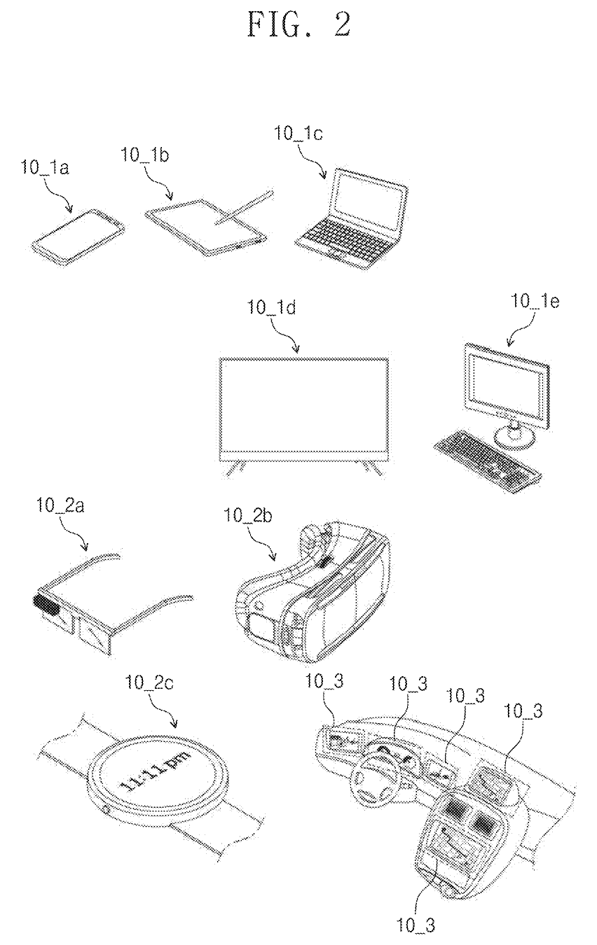

FIG. 2 illustrates schematic views of electronic devices according to various embodiments. FIG. 2 illustrates examples of various electronic devices to which a display device according to some embodiments is applied.

FIG. 2 illustrates a smart phone 10_1a, a tablet PC 10_1b, a laptop computer 10_1c, a TV 10_1d, and a desk monitor 10_1e as examples of electronic devices.

The smart phone 10_1a may include an input module, such as a touch sensor, and a communication module in addition to the display module DM. The smart phone 10_1a may process information received through the communication module or the input module and may display the information through the display module of the display device.

Similarly to the smart phone 10_1a, the tablet PC 10_1b, the laptop computer 10_1c, the TV 10_1d, and the desk monitor 10_1e may also include a display module and an input module and may further include a communication module in some cases.

FIG. 2 illustrates a case in which an electronic device including a display module is applied to a wearable electronic device. The wearable electronic device may be smart glasses 10_2a, a head mounted display 10_2b, or a smart watch 10_2c.

The smart glasses 10_2a and the head mounted display 10_2b may include a display module that outputs a display image and a reflector that reflects the output display image and displays the image to a user’s eyes and may provide a virtual reality or augmented reality screen to the user.

The smart watch 10_2c may include a biometric sensor as an input device and may provide biometric information recognized through the biometric sensor to a user through a display module.

FIG. 2 illustrates a case in which an electronic device including a display module is applied to a vehicle. For example, an electronic device 10_3 may be applied to an instrument panel or a center fascia of a vehicle or may be applied to a center information display located on a dashboard of the vehicle or a room mirror display replacing a side mirror.

According to some embodiments, an electronic device to which a display device according to some embodiments is applied may include not only devices that focus on displaying a screen, such as a billboard, an electronic board, and a game machine, but also various home appliances that display information through a display module, such as a refrigerator, a washing machine, a dryer, an air conditioner, and a robot vacuum cleaner. In addition, when a display module has a function of transmitting light, it may be applied to electronic devices such as a smart window or a transparent display device that displays a background and a display image together. The types of electronic devices according to embodiments are not limited to the above examples, and application of various other electronic devices not illustrated may also be possible.

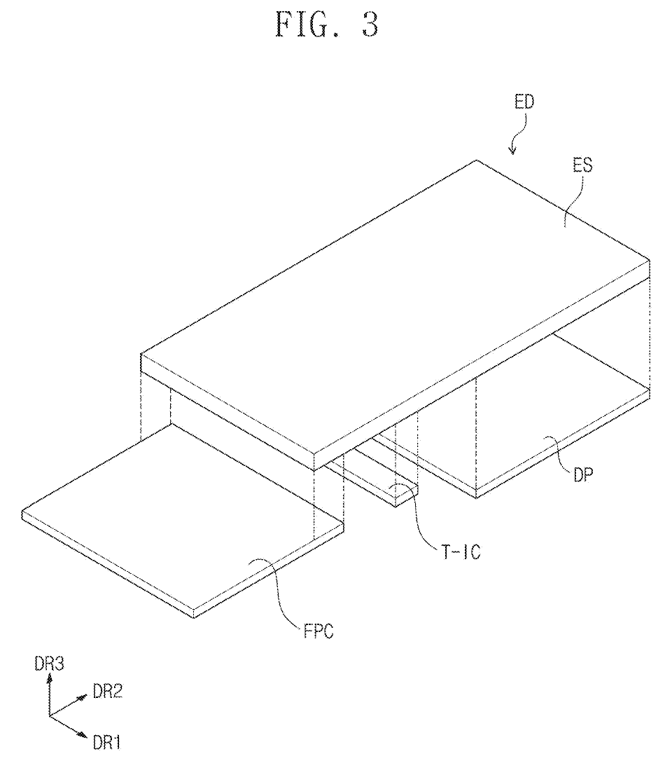

FIG. 3 is an exploded perspective view of the electronic device ED according to some embodiments.

Referring to FIG. 3, the electronic device ED according to some embodiments may include a display panel DP, an encapsulation substrate ES, a timing controller T-IC, and a flexible circuit board FPC.

The display panel DP may have a planar shape similar to a rectangle having one side in a first direction DR1 and an opposite side in a second direction DR2 crossing the first direction DR1. The one side of the display panel DP in the first direction DR1 and the opposite side of the display panel DP in the second direction DR2 may have different lengths. The planar shape of the display panel DP is not limited to a rectangle and may be formed similarly to other polygons, a circle, or an oval. The display panel DP may be spaced apart from the timing controller T-IC and the flexible circuit board FPC.

One side of the encapsulation substrate ES in the first direction DR1 and an opposite side of the encapsulation substrate ES in the second direction DR2 may have different lengths. The planar shape of the encapsulation substrate ES is not limited to a rectangle and may be formed similarly to other polygons, a circle, or an oval. The encapsulation substrate ES may have a planar shape similar to a rectangle having one side in the first direction DR1 and an opposite side in the second direction DR2 crossing the first direction DR1. According to some embodiments, the length of the opposite side of the encapsulation substrate ES in the second direction DR2 may be longer than the length of the opposite side of the display panel DP in the second direction DR2.

The encapsulation substrate ES may electrically connect the display panel DP, the timing controller T-IC, and the flexible circuit board FPC. The encapsulation substrate ES may be a substrate located over the display panel DP and may be arranged to face the display panel DP. The encapsulation substrate ES may be electrically connected to a plurality of pads in a pad area of the display panel DP through an adhesive member such as an anisotropic conductive adhesive layer to be described in more detail below. In addition, the encapsulation substrate ES may be electrically connected with the timing controller T-IC and the flexible circuit board FPC through an anisotropic conductive adhesive layer.

The timing controller T-IC may convert a signal transferred from the flexible circuit board FPC into a driving signal depending on timing signals. The timing controller T-IC may transfer a signal to a driver chip of the display panel DP and may control the display panel DP.

The flexible circuit board FPC may be a flexible printed circuit board having a flexible material and may partially overlap the encapsulation substrate ES. However, the flexible circuit board FPC is not limited to being spaced apart from the display panel DP and may be bonded to the pad area of the display panel DP.

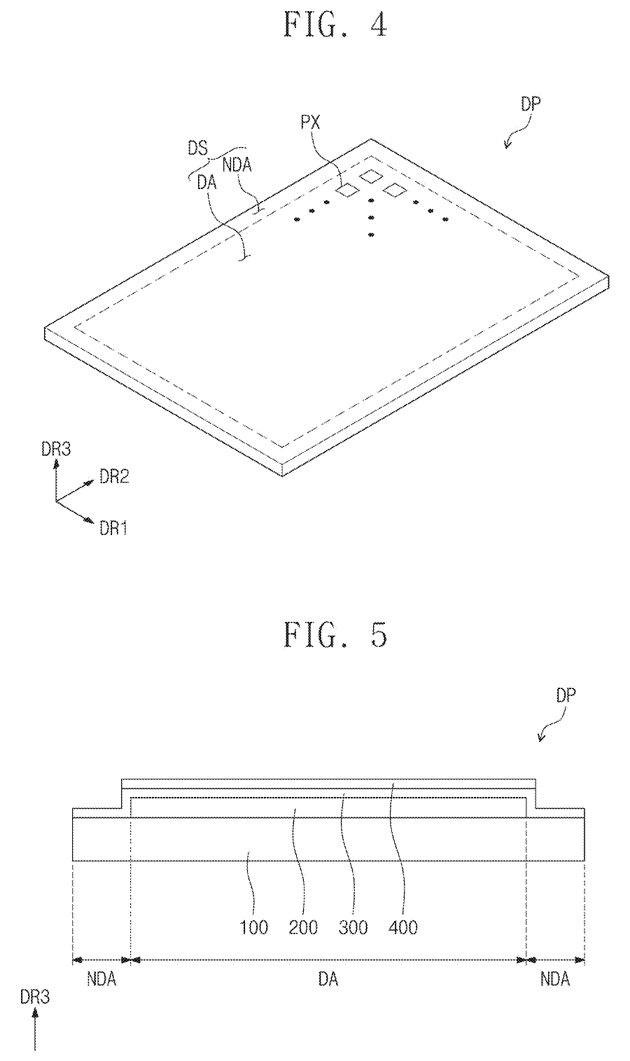

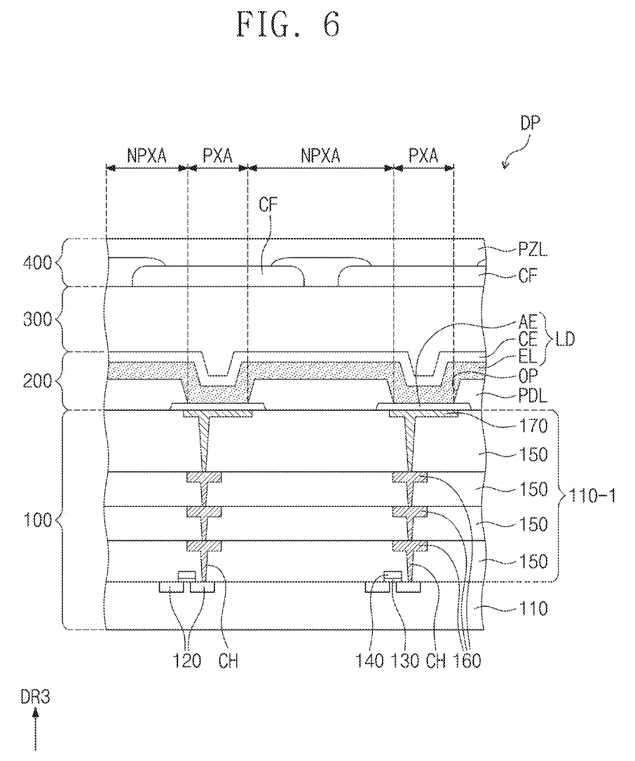

FIG. 4 is a perspective view of the display panel DP according to some embodiments. FIG. 5 is a schematic sectional view of the display panel DP according to some embodiments. FIG. 6 is a sectional view of the display panel DP according to some embodiments.

Referring to FIG. 4, the display panel DP according to some embodiments of the present disclosure includes a display surface DS that is parallel (or substantially parallel) to a plane defined by the first direction DR1 and the second direction DR2. An image is displayed through the display surface DS. The normal direction of the display surface DS is defined as a third direction DR3. The expressions “when viewed from above the plane” or “in a plan view” used herein means that it is viewed from the third direction DR3 toward a display surface of the display panel DP.

The display surface DS may include a display area DA and a non-display area NDA around (e.g., in a periphery or outside a footprint of) the display area DA. The display area DA displays images, and the non-display area NDA does not display images. The non-display area NDA may surround (e.g., in a periphery or outside a footprint of) the display area DA. However, without being limited thereto, the non-display area NDA may not be located on one side of the display area DA.

A plurality of pixels PX may be located in the display area DA. The pixels PX may be arranged in a matrix form. Each of the pixels PX may include a pixel circuit and a light emitting element. The pixels PX may all generate light of the same color. According to some embodiments of the present disclosure, the pixels PX may include a plurality of groups that generate light of different colors.

Referring to FIG. 5, the display panel DP may include a circuit board 100, a light emitting element layer 200, a thin film encapsulation layer 300, and an optical layer 400. As illustrated in FIG. 5, the display panel DP may include a display area DA and a non-display area NDA around (e.g., in a periphery or outside a footprint of) the display area DA, and the light emitting element layer 200 may be located in the display area DA.

The circuit board 100 may include a pixel circuit. The pixel circuit may control operation of a light emitting element in the light emitting element layer 200. The pixel circuit may include at least one transistor. The circuit board 100 may include a CMOS wafer. The CMOS wafer may include an nMOSFET (NMOS) and a pMOSFET (PMOS) complementarily connected with each other. A plurality of pixel areas are regularly arranged in the CMOS wafer, and a pixel circuit is located in each of the pixel areas.

The light emitting element layer 200 may include the light emitting element electrically connected to the pixel circuit. According to some embodiments, the light emitting element may include an organic light emitting element, but embodiments according to the present disclosure are not necessarily limited thereto. The light emitting element may generate light of a first color, light of a second color, and light of a third color. The light of the first color, the light of the second color, and the light of the third color may be mixed to form white light. However, without being limited thereto, the light emitting element may generate only the light of the first color.

The thin film encapsulation layer 300 may protect the light emitting element layer 200 from foreign matter such as moisture, oxygen, and dust particles. The thin film encapsulation layer 300 may include a stack structure of an inorganic layer, an organic layer, and an inorganic layer, but embodiments according to the present disclosure are not necessarily limited thereto. The thin film encapsulation layer 300 may seal the light emitting element layer 200, and thus the durability and lifetime of the light emitting element layer 200 may be relatively improved.

The optical layer 400 may include a color filter. The color filter may transmit only light in a specific wavelength range among the light generated by the light emitting element and may absorb light in other wavelength ranges. The optical layer 400 may include a plurality of color filters. The optical layer 400 may include a first color filter that selectively transmits the light of the first color, a second color filter that selectively transmits the light of the second color, and a third color filter that selectively transmits the light of the third color.

FIG. 6 illustrates a cross-section of the display panel DP of FIG. 5 in detail. FIG. 6 may include an emissive area PXA and a non-emissive area NPXA. Each of the pixels PX (refer to FIG. 4) includes a light emitting element LD and a pixel circuit connected to the light emitting element LD.

The circuit board 100 may be a complementary metal oxide semiconductor (CMOS) circuit board. The circuit board 100 includes a semiconductor substrate 110. The semiconductor substrate 110 may be a silicon substrate, a germanium substrate, or a silicon-germanium substrate. A plurality of transistors may be formed in the semiconductor substrate 110 through a semiconductor process.

Source/drain areas 120 may be areas doped with a dopant. A pair of source/drain areas 120 may define a transistor together with a gate 140 to be described below. The source/drain areas 120 may be the source or drain of the transistor depending on a signal flow. That is, when one of the source/drain areas 120 is the source area 120, the other may be the drain area 120.

A wiring layer 110-1 is located on the semiconductor substrate 110. The wiring layer 110-1 may include one or more insulating layers 130 and 150 and one or more conductive patterns 140 and 160. According to some embodiments, a wiring layer 110-1 including a plurality of insulating layers 130 and 150 and a plurality of conductive patterns 140 and 160 is illustrated as an example. The plurality of insulating layers 130 and 150 may include a silicon carbon nitride (SiCN)-based inorganic layer or a silicon oxide (SiO)-based inorganic layer. The plurality of conductive patterns 140 and 160 may be formed of one of copper (Cu), aluminum (Al), tungsten (W), molybdenum (Mo), chromium (Cr), gold (Au), titanium (Ti), nickel (Ni), and neodymium (Nd), or an alloy containing one of the aforementioned materials.

The gate insulating layer 130 and the gates 140 are located on the semiconductor substrate 110. The gates 140 may include a metal. Each of the gates 140 is arranged to correspond to a pair of source/drain areas 120. The gate insulating layer 130 may include insulating patterns arranged to correspond to the gates 140.

The plurality of intermediate insulating layers 150 are located on the semiconductor substrate 110. Contact holes CH are defined in the intermediate insulating layers 150. The conductive patterns 160 are located in the contact holes CH of the intermediate insulating layers 150, respectively. The conductive pattern 160 located on the upper side may be connected with the conductive pattern located on the lower side, and the conductive pattern 160 located on the lowermost side may be directly connected with the source/drain areas 120.

A reflective conductive pattern 170 penetrating the intermediate insulating layer 150 located on the uppermost side and electrically connected to the conductive pattern 160, is located over the semiconductor substrate 110. The reflective conductive pattern 170 may be electrically connected with a first electrode AE, which will be described below. Accordingly, the source/drain areas 120 of the transistor may be electrically connected with the first electrode AE in the light emitting element layer 200 through at least one conductive pattern 160 and the reflective conductive pattern 170. The reflective conductive pattern 170 may serve as a reflective layer in the light emitting element layer 200. The reflective conductive pattern 170 may prevent or reduce light generated from the light emitting element layer 200 from being absorbed by the opaque semiconductor substrate 110. In addition, the reflective conductive pattern 170 may reflect light generated from the light emitting element layer 200 in the third direction DR3, thereby relatively improving light emission efficiency.

The reflective conductive pattern 170 is not particularly limited as long as it is formed of a material with high conductivity and high reflectivity. The reflective conductive pattern 170 may include copper (Cu), tungsten (W), or silver (Ag). The reflective conductive pattern 170 may include an alloy containing copper (Cu), tungsten (W), or silver (Ag).

The upper surface of the reflective conductive pattern 170 may define the same plane as the upper surface of the uppermost intermediate insulating layer 150. The reflective conductive pattern 170 may be formed by a chemical/physical polishing process, for example, a damascene process.

The light emitting element layer 200 may be located on the upper surface of the uppermost intermediate insulating layer 150. The light emitting element LD and a pixel defining layer PDL may be located on the upper surface of the uppermost intermediate insulating layer 150. The light emitting element LD may include the first electrode AE, an emissive layer EL located on the first electrode AE, and a second electrode CE. According to some embodiments, the first electrode AE may be an anode, and the second electrode CE may be a cathode.

The first electrode AE may be directly located on the uppermost intermediate insulating layer 150 and may be directly located on the reflective conductive pattern 170. The first electrode AE may make contact with the upper surface of the uppermost intermediate insulating layer 150 and the upper surface of the reflective conductive pattern 170. The first electrode AE may be electrically connected with the reflective conductive pattern 170 through direct contact.

The first electrode AE may include a transparent conductive oxide pattern. The transparent conductive oxide pattern may include indium tin oxide (ITO), indium zinc oxide (IZO), indium gallium zinc oxide (IGZO), zinc oxide (ZnOx), indium oxide (In₂O₃), or aluminum-doped zinc oxide (AZO) into which holes are easily injected. The first electrode AE may have a single-layer structure or a multi-layer structure.

The pixel defining layer PDL may be located on the uppermost intermediate insulating layer 150. The pixel defining layer PDL may be an organic layer. Although the pixel defining layer PDL having a single-layer structure is illustrated in these embodiments, the present disclosure is not limited thereto. An opening OP is defined in the pixel defining layer PDL to partially expose the first electrode AE. According to some embodiments, the emissive area PXA may be defined to correspond to a partial area of the first electrode AE exposed by the opening OP.

The emissive layer EL is located on the first electrode AE and the pixel defining layer PDL. The second electrode CE is located on the emissive layer EL. The emissive layer EL of the light emitting elements LD may have a one-body shape, and the second electrode CE of the light emitting elements LD may have a one-body shape. The emissive layer EL and the second electrode CE may commonly overlap the emissive area PXA and the non-emissive area NPXA.

The thin film encapsulation layer 300 may be located on the emissive layer EL. According to some embodiments, the thin film encapsulation layer 300 may include a plurality of thin films and may include, for example, a stack structure in which an inorganic encapsulation layer, an organic encapsulation layer, and an inorganic encapsulation layer are sequentially stacked one above another.

The optical layer 400 may be located on the thin film encapsulation layer 300. The optical layer 400 may include a color filter CF and a planarization layer PZL located on the color filter CF.

The optical layer 400 may include a plurality of color filters CF and may include a first color filter, a second color filter, and a third color filter that correspond to the emissive areas PXA, respectively. For example, the first color filter transmits the light of the first color among the light of the first color, the light of the second color, and the light of the third color generated from the emissive layer EL, the second color filter transmits the light of the second color among the light of the first color, the light of the second color, and the light of the third color generated from the emissive layer EL, and the third color filter transmits the light of the third color among the light of the first color, the light of the second color, and the light of the third color generated from the emissive layer EL.

The planarization layer PZL may be located on the color filters CF. The planarization layer PZL may include an organic material. According to some embodiments, the optical layer 400 may further include a light blocking pattern.

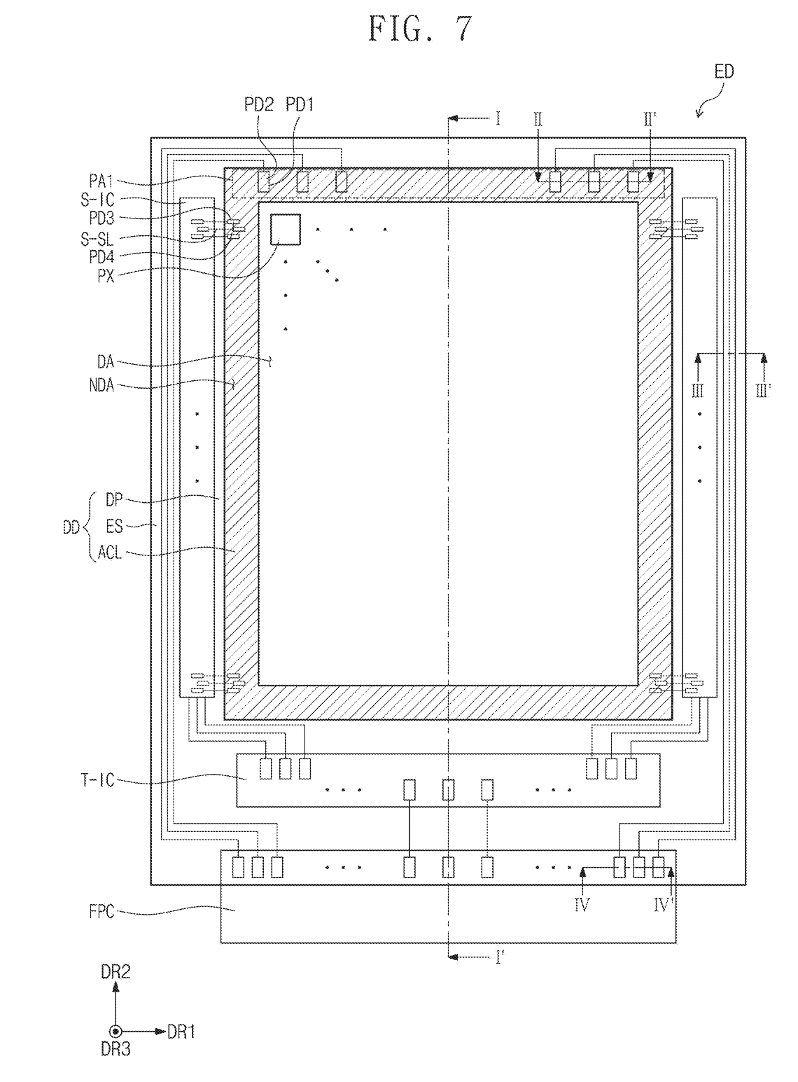

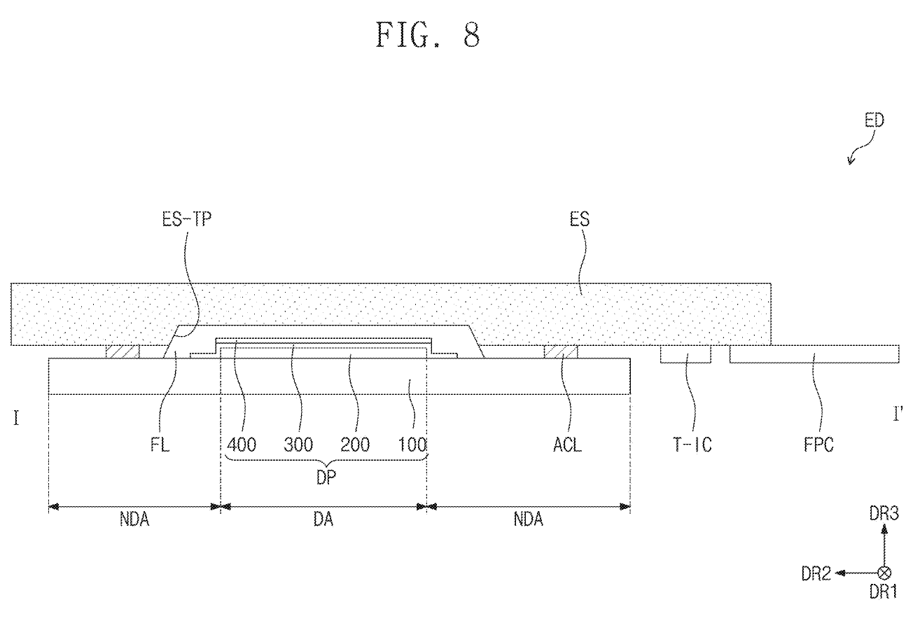

FIG. 7 is a schematic plan view of the electronic device ED according to some embodiments of the present disclosure. FIG. 8 is a schematic sectional view of the electronic device ED according to some embodiments of the present disclosure. FIG. 8 is a sectional view of the electronic device ED corresponding to the line I-I’ of FIG. 7. Some detailed description of components identical to the components described with reference to FIGS. 3 to 6 may be omitted.

Referring to FIGS. 7 and 8, a display device DD includes the display panel DP, the encapsulation substrate ES facing the display panel DP, and an anisotropic conductive adhesive layer ACL. The electronic device ED may further include the display device DD, a source driver chip S-IC, the timing controller T-IC, and the flexible circuit board FPC.

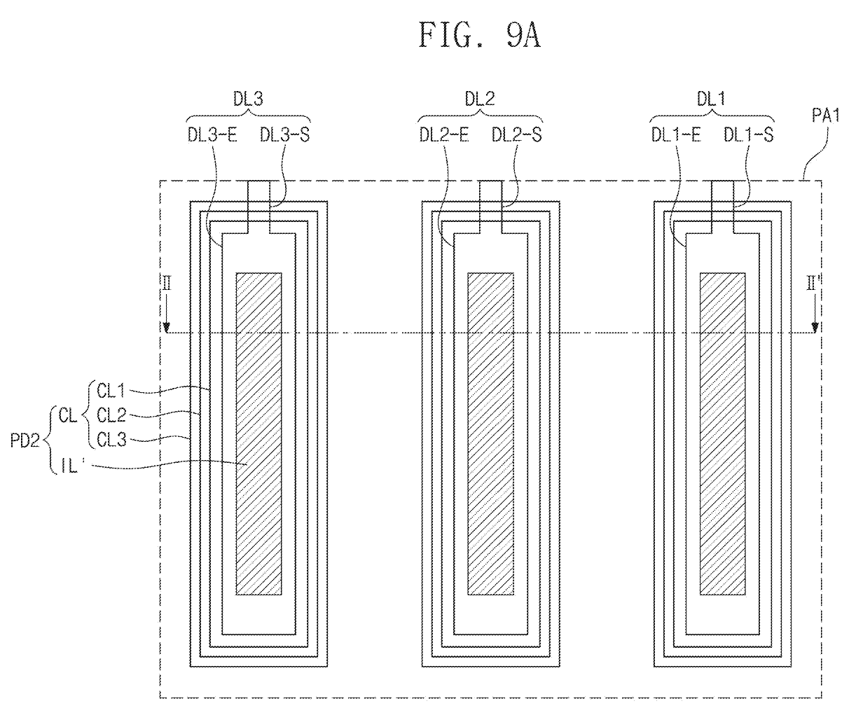

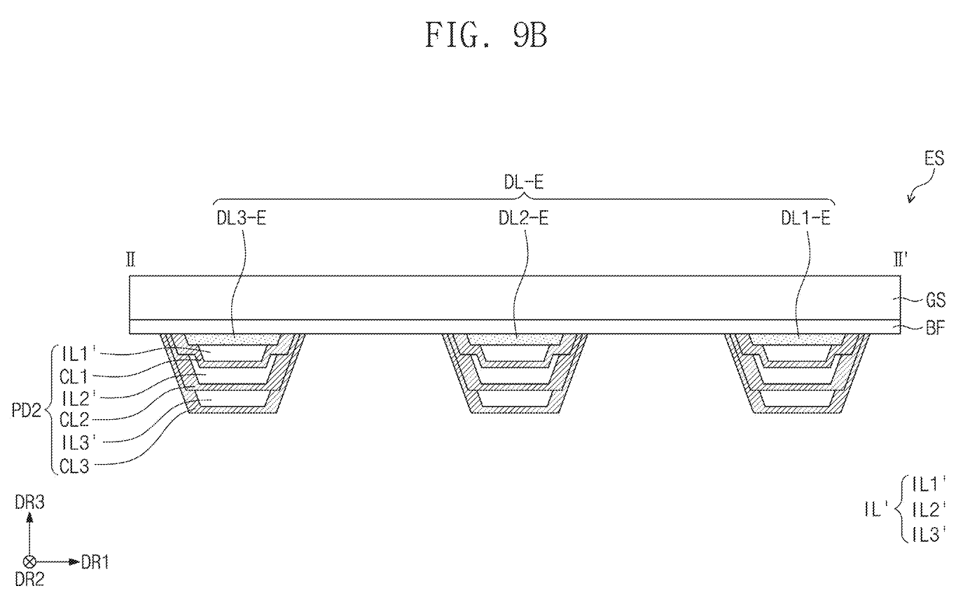

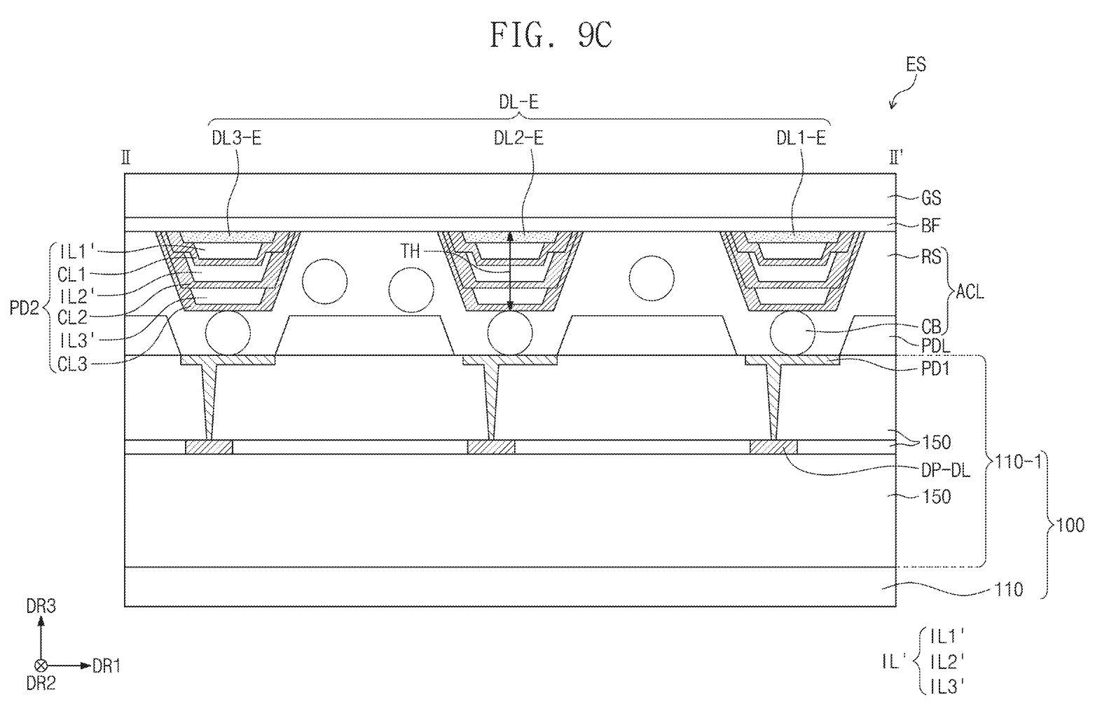

The encapsulation substrate ES may be electrically connected with the display panel DP through the anisotropic conductive adhesive layer ACL. The encapsulation substrate ES may electrically connect the display panel DP to the source driver chip S-IC, the timing controller T-IC, and the flexible circuit board FPC through a signal line within the encapsulation substrate ES. That is, the timing controller T-IC and the flexible circuit board FPC may be electrically connected through wiring of the encapsulation substrate ES. That is, the display panel DP and electronic components may be electrically connected through signal lines located on one surface of the encapsulation substrate ES. Accordingly, signal lines that could not be arranged due to the limitation of the number of lines in the display panel DP may be additionally located on a glass substrate GS (refer to FIG. 9b) included in the encapsulation substrate ES, and thus high resolution may be implemented.

The anisotropic conductive adhesive layer ACL may be located in the non-display area NDA of the display panel DP and may couple the encapsulation substrate ES and the display panel DP. The anisotropic conductive adhesive layer ACL may be located between the display panel DP and the encapsulation substrate ES and may couple the display panel DP and the encapsulation substrate ES. The anisotropic conductive adhesive layer ACL may have a closed-line shape when viewed from above the plane (e.g., in a plan view). The anisotropic conductive adhesive layer ACL may have a closed-line shape surrounding four sides of the display area DA of the display panel DP.

According to some embodiments, the display panel DP may include a pad area PA1 located in the non-display area NDA. A first pad PD1 of the display panel DP and a second pad PD2 of the encapsulation substrate ES that corresponds to the first pad PD1 may be located in the pad area PA1. Referring to FIG. 7, the first pad PD1 means a pad included in the display panel DP, and the second pad PD2 means a pad that corresponds to the first pad PD1 and that is included in the encapsulation substrate ES. The anisotropic conductive adhesive layer ACL may be located between the first pad PD1 and the second pad PD2 and may electrically connect the first pad PD1 and the second pad PD2. Accordingly, the display panel DP and the encapsulation substrate ES may be electrically connected.

According to some embodiments, the display panel DP may further include a third pad PD3 located in the non-display area NDA and electrically connected with the source driver chip S-IC. The third pad PD3 may be electrically connected with a signal line within the display panel DP. For example, the third pad PD3 may be electrically connected with a scan line among a plurality of signal lines within the display panel DP. The encapsulation substrate ES may include a fourth pad PD4 corresponding to the third pad PD3. The encapsulation substrate ES may further include a sub-signal line S-SL electrically connected with the source driver chip S-IC, and the fourth pad PD4 may be electrically connected with the sub-signal line S-SL. Likewise to the first pad PD1 and the second pad PD2, the third pad PD3 and the fourth pad PD4 may be electrically connected through the anisotropic conductive adhesive layer ACL.

Referring to FIG. 8, the encapsulation substrate ES may be electrically connected with the display panel DP through the anisotropic conductive adhesive layer ACL. The timing controller T-IC and the flexible circuit board FPC may be located on the lower surface of the encapsulation substrate ES.

According to some embodiments, the area of the encapsulation substrate ES may be greater than the area of the display panel DP. That is, the encapsulation substrate ES may overlap the display panel DP, the timing controller T-IC, and the flexible circuit board FPC. The area of the encapsulation substrate ES may be greater than the area of the circuit board 100 of the display panel DP.

The encapsulation substrate ES may include, on the lower surface of the encapsulation substrate ES, a recess ES-TP corresponding to the display panel DP and facing toward the upper surface of the encapsulation substrate ES. The recess ES-TP may be recessed toward the inside of the encapsulation substrate ES.

The electronic device ED may further include a filling layer FL located between the display panel DP and the encapsulation substrate ES. The filling layer FL may be located inside the anisotropic conductive adhesive layer ACL and may fill the empty space between the recess ES-TP of the encapsulation substrate ES and the display panel DP. That is, the filling layer FL may be located in the recess ES-TP. The filling layer FL may include a silicone gel, an epoxy resin, and an acrylic resin that have high light transmittance.

The anisotropic conductive adhesive layer ACL may be located in the pad areas of the display panel DP and the encapsulation substrate ES. Accordingly, the anisotropic conductive adhesive layer ACL may prevent or reduce the filling layer FL flowing out to the periphery of the display panel DP. The anisotropic conductive adhesive layer ACL may be located between the encapsulation substrate ES and the timing controller T-IC and may electrically connect the encapsulation substrate ES and the timing controller T-IC. Likewise, the anisotropic conductive adhesive layer ACL may also be located between the encapsulation substrate ES and the flexible circuit board FPC and may electrically connect the encapsulation substrate ES and the flexible circuit board FPC.

According to some embodiments, the electronic device ED may not include a frit inside or outside the anisotropic conductive adhesive layer ACL. The frit may mean a structure having glass properties formed by melting and curing glass in the form of powder to which an additive is added. Since the display panel DP and the encapsulation substrate ES are bonded through the anisotropic conductive adhesive layer ACL, a sealing process of curing the frit may be omitted. As the sealing process is omitted, a problem of non-uniform curing due to ultraviolet light penetrating a bonding area in an ultraviolet curing process of the frit may be resolved.

According to some embodiments, the display panel DP may include the display area DA where the light emitting element LD (refer to FIG. 6) is located and the non-display area NDA around the display area DA. As illustrated in FIG. 8, the width of the non-display area NDA may be greater than or equal to 400 μm and less than 600 μm. In this specification, an area of the non-display area where the circuit board 100 of the display panel DP and the encapsulation substrate ES are coupled may be referred to as a border area. As the frit is not included in the electronic device ED as described above, the border area that had to be considered for the width of the frit may be reduced. Accordingly, the proportion of the display area DA in the electronic device ED may be expanded, and thus the resolution may be increased.

FIG. 9A is an enlarged plan view of the pad area PA1 according to some embodiments of the present disclosure. FIG. 9B is a sectional view of the encapsulation substrate ES according to some embodiments of the present disclosure. FIG. 9C is a sectional view illustrating a shape in which the encapsulation substrate ES and the display panel DP are coupled according to some embodiments of the present disclosure. FIG. 9B is a sectional view of the encapsulation substrate ES corresponding to the line II-II’ of FIG. 9A, and FIG. 9C is a sectional view illustrating a shape in which the encapsulation substrate ES of FIG. 9B and the display panel DP are coupled through the anisotropic conductive adhesive layer ACL (refer to FIG. 7).

The encapsulation substrate ES in the pad area PA1 may include the second pad PD2. The encapsulation substrate ES may include the glass substrate GS, at least one insulating layer IL located on one surface of the glass substrate GS, signal lines DL1, DL2, and DL3 located on the one surface of the glass substrate GS, and second pads PD2 electrically connected to the signal lines DL1, DL2, and DL3, respectively. For convenience, the second pads to be described below may be described based on one second pad PD2.

According to some embodiments, the second pad PD2 may include a plurality of conductive patterns CL and a plurality of insulating patterns IL. The plurality of insulating patterns IL and the plurality of conductive patterns CL may be alternately stacked, and neighboring conductive patterns among the plurality of conductive patterns CL may make contact with each other.

A buffer layer BF may be further included on the one surface of the glass substrate GS. An end portion DL-E of a data line may be located on the buffer layer BF. The second pad PD2 may include a first insulating pattern IL1 overlapping the end portion DL-E of the data line and a first conductive pattern CL1 electrically connected to the end portion DL-E of the data line. The second pad PD2 may include a second insulating pattern IL2 that overlaps the first insulating pattern IL1 and that is located on the first conductive pattern CL1, a second conductive pattern CL2 located on the first conductive pattern CL1 and electrically connected to the first conductive pattern CL1, a third insulating pattern IL3 that overlaps the second insulating pattern IL2 and that is located on the second conductive pattern CL2, and a third conductive pattern CL3 located on the second conductive pattern CL2 and electrically connected to the second conductive pattern CL2. As the second pad PD2 includes the plurality of insulating patterns IL and the plurality of conductive patterns CL, the thickness of the second pad PD2 may be increased.

An end portion DP-DL of a signal line of the display panel included in the wiring layer 110-1 of the display panel may be connected with the first pad PD1. The first pad PD1 may correspond to the second pad PD2 of the encapsulation substrate ES, and the first pad PD1 and the second pad PD2 may be electrically connected through the anisotropic conductive adhesive layer ACL. The first pad PD1 in FIG. 9C may include the same material as the reflective electrode 170 of FIG. 6 and may be located in the same layer as the reflective electrode 170.

According to some embodiments, the anisotropic conductive adhesive layer ACL may include a photocurable resin RS and conductive balls CB mixed in the photocurable resin RS. The photocurable resin RS may not be completely cured after ultraviolet light is irradiated thereto, but may be completely cured by an additional heat treatment condition. For example, the photocurable resin RS may include an epoxy resin or an acrylic resin and an additive such as a UV-retarding curing agent, and therefore curing by ultraviolet light may be delayed. The photocurable resin RS whose curing is delayed by ultraviolet light may be cured under a temperature condition of 60°C to 120°C and may be cured under a temperature condition of 80°C to 100°C. The photocurable resin RS may be thermally cured at a relatively low temperature when compared to a thermosetting resin, and thus thermal damage to the circuit board 100 may be prevented or reduced.

According to some embodiments, the maximum thickness TH of the second pad PD2 may range from 4 μm to 7 μm. As the insulating patterns IL1, IL2, and IL3 are alternately stacked between the conductive patterns CL1, CL2, and CL3, the thickness of the second pad PD2 may be increased. The conductive balls CB may be in contact between the second pad PD2 and the first pad PD1, and thus the display panel DP and the glass substrate GS may be electrically connected. That is, as the thickness of the second pad PD2 is increased, the contact area with the conductive balls CB may be increased, and the non-contact of the conductive balls CB may be reduced. Thus, electrical reliability may be relatively improved.

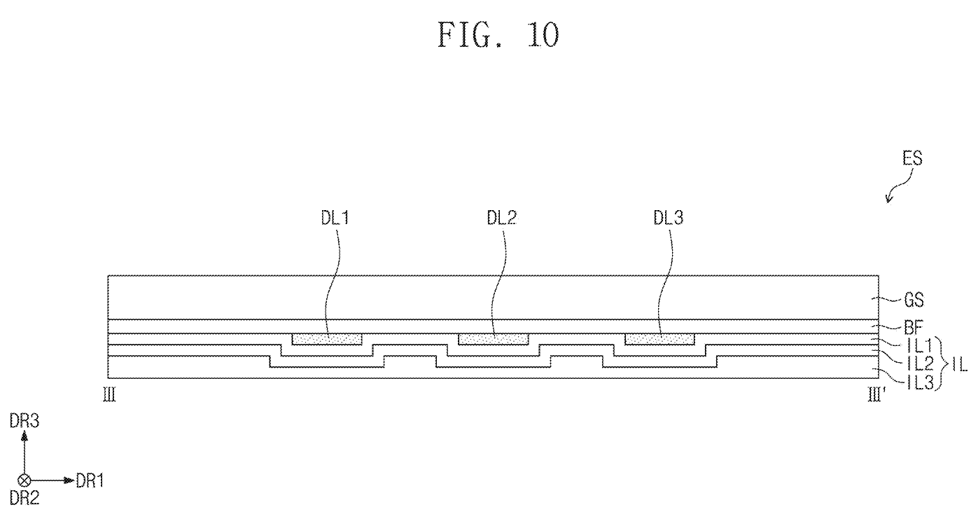

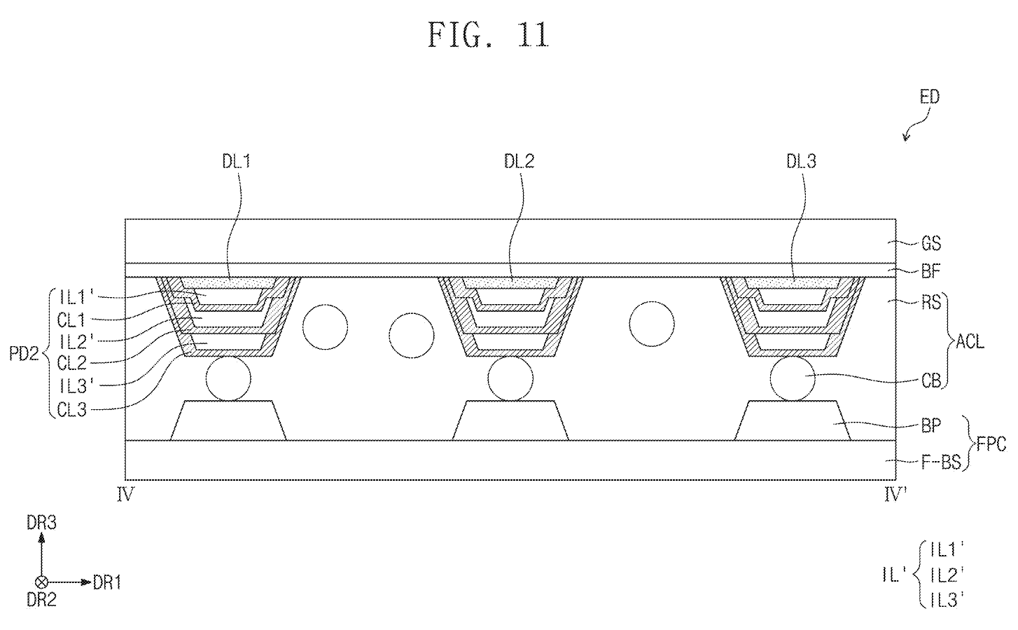

FIG. 10 is a sectional view of the encapsulation substrate ES corresponding to the line III-III’ of FIG. 7. FIG. 11 is a sectional view of the electronic device ED corresponding to the line IV-IV’ of FIG. 7. FIG. 10 is a sectional view of the encapsulation substrate ES rather than a pad area. FIG. 11 is a sectional view of a pad area between the encapsulation substrate ES and the flexible circuit board FPC.

Referring to FIG. 10, the signal lines DL1, DL2, and DL3 may be located on the buffer layer BF. At least one insulating layer IL may be located on the signal lines DL1, DL2, and DL3. The first insulating layer IL1 may be an inorganic layer that covers the signal lines DL1, DL2, and DL3. The second insulating layer IL2 located on the first insulating layer IL1 may be an inorganic layer and/or an organic layer and may have a single-layer structure or a multi-layer structure. The third insulating layer IL3 located on the second insulating layer IL2 may be a planarization layer and may be an organic layer.

FIG. 11 is the same as FIG. 9C except that the electronic component connected with the encapsulation substrate ES is the flexible circuit board FPC. The flexible circuit board FPC may include a base layer F-BS and bump electrodes BP mounted on the base layer F-BS. The bump electrodes BP of the flexible circuit board FPC may be electrically connected with the second pad PD2 through the conductive balls CB of the anisotropic conductive adhesive layer ACL.

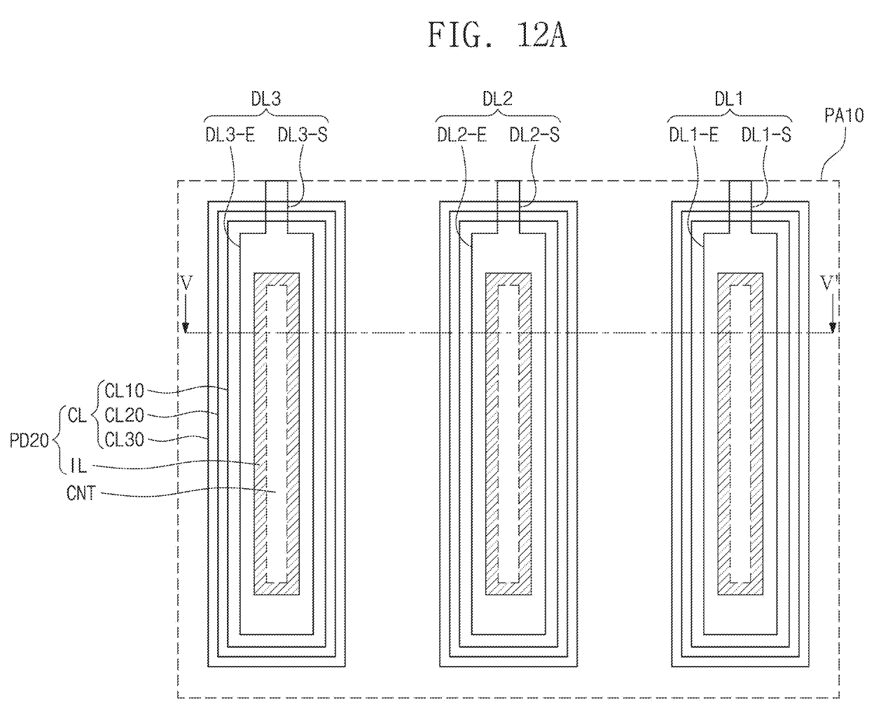

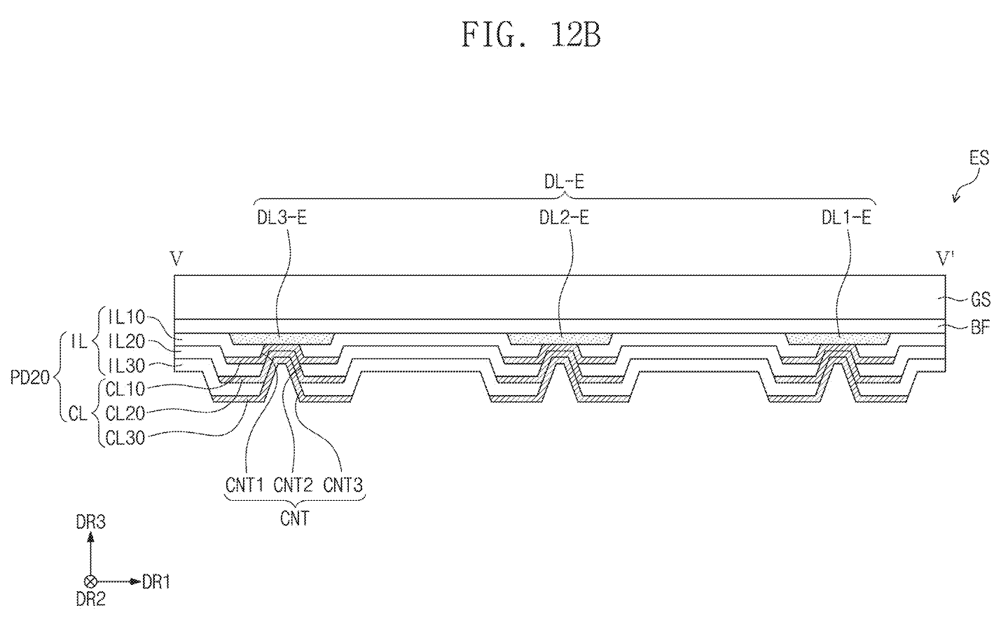

FIG. 12A is an enlarged plan view of a pad area PA10 according to some embodiments, and FIG. 12B is a sectional view of an encapsulation substrate ES according to some embodiments. Some detailed description of components identical to the components described with reference to FIGS. 9A and 9B may be omitted.

FIG. 12A is the same as FIG. 9 except that a contact hole CNT is formed in an insulating layer IL when viewed from above a plane (e.g., in a plan view). Referring to FIG. 12B, the insulating layer IL may include a first insulating layer IL10, a second insulating layer IL20 located on the first insulating layer IL10, and a third insulating layer IL30 located on the second insulating layer IL20. Conductive patterns CL of FIG. 12B may include a first conductive pattern CL10 electrically connected to an end portion of a signal line through a first contact hole CNT1 penetrating the first insulating layer IL10, a second conductive pattern CL20 electrically connected to the first conductive pattern CL10 through a second contact hole CNT3 penetrating the second insulating layer IL20, and a third conductive pattern CL30 electrically connected to the second conductive pattern CL20 through a third contact hole CNT3 penetrating the third insulating layer IL30. A second pad PD20 of FIG. 12B may include the first conductive pattern CL10, the second conductive pattern CL20, and the third conductive pattern CL30. The thickness of the second pad PD20 of FIG. 12B may be increased by the plurality of insulating patterns IL alternately arranged between the plurality of conductive patterns CL, and thus electrical reliability with electronic components may be relatively improved.

According to some embodiments of the present disclosure, the display panel and the encapsulation substrate may be electrically connected through the anisotropic conductive adhesive layer having the closed-line shape. As the bonding is performed by the anisotropic conductive adhesive layer having the closed-line shape in the pad area, the border area of the display device may be reduced. Furthermore, the resin of the anisotropic conductive adhesive layer may be cured at a low temperature so that non-uniform curing may be prevented or reduced and thus curing performance may be relatively improved.

In addition, since the conductive patterns and the insulating patterns are alternately stacked, the thickness of the pad may be increased so that the electrical reliability between the display panel and the encapsulation substrate may be relatively improved. Accordingly, the bonding reliability of the display device and the electronic device including the display device may be relatively improved.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a display panel including a first pad;
an encapsulation substrate facing the display panel, the encapsulation substrate including:
a glass substrate;
at least one insulating layer on one surface of the glass substrate;
a signal line on the one surface of the glass substrate; and
a second pad electrically connected to the signal line and corresponding to the first pad; and
an anisotropic conductive adhesive layer having a closed-line shape, the anisotropic conductive adhesive layer being between the display panel and the encapsulation substrate to couple the display panel and the encapsulation substrate and configured to electrically connect the first pad and the second pad,
wherein the display panel comprises:
a semiconductor substrate;
a wiring layer on the semiconductor substrate and comprising the first pad; and
a light emitting element on the wiring layer.

2. The display device of claim 1, wherein the second pad comprises a plurality of conductive patterns and a plurality of insulating patterns,
wherein the plurality of insulating patterns and the plurality of conductive patterns are alternately stacked, and
wherein neighboring conductive patterns among the plurality of conductive patterns contact each other.

3. The display device of claim 1, wherein the second pad comprises:
a first insulating pattern overlapping an end portion of the signal line;
a first conductive pattern electrically connected to the end portion of the signal line;
a second insulating pattern overlapping the first insulating pattern and located on the first conductive pattern;
a second conductive pattern on the first conductive pattern and electrically connected to the first conductive pattern;
a third insulating pattern overlapping the second insulating pattern and located on the second conductive pattern; and
a third conductive pattern on the second conductive pattern and electrically connected to the second conductive pattern.

4. The display device of claim 1, wherein the at least one insulating layer comprises a first insulating layer, a second insulating layer, and a third insulating layer, and
wherein the second pad comprises:
a first conductive pattern electrically connected to an end portion of the signal line through a first contact hole penetrating the first insulating layer;
a second conductive pattern electrically connected to the first conductive pattern through a second contact hole penetrating the second insulating layer on the first insulating layer; and
a third conductive pattern electrically connected to the second conductive pattern through a third contact hole penetrating the third insulating layer on the second insulating layer.

5. The display device of claim 1, wherein a maximum thickness of the second pad is in a range of 4 micrometers (μm) to 7 μm.

6. The display device of claim 1, wherein the anisotropic conductive adhesive layer comprises a photocurable resin and conductive balls mixed in the photocurable resin.

7. The display device of claim 6, wherein the photocurable resin is cured at 120℃ or less.

8. The display device of claim 1, wherein an area of the encapsulation substrate is larger than an area of the semiconductor substrate in a plan view.

9. The display device of claim 1, wherein the display panel includes a display area where the light emitting element is located and a non-display area around the display area, and
wherein a width of the non-display area is greater than or equal to 400 micrometers (μm) and less than 600 μm.

10. The display device of claim 1, further comprising:
a filling layer between the display panel and the encapsulation substrate,
wherein the filling layer is inside the anisotropic conductive adhesive layer.

11. The display device of claim 10, wherein the encapsulation substrate includes, on a lower surface thereof, a recess corresponding to the display panel and facing toward an upper surface of the encapsulation substrate, and
wherein the filling layer is in the recess.

12. The display device of claim 1, wherein a frit configured to couple the display panel and the encapsulation substrate is not included inside or outside the anisotropic conductive adhesive layer.

13. An electronic device comprising:
a display panel including a first pad;
an encapsulation substrate facing the display panel, the encapsulation substrate including:
a glass substrate;
at least one insulating layer on one surface of the glass substrate;
a signal line on the one surface of the glass substrate; and
a second pad electrically connected to the signal line and corresponding to the first pad;
a timing controller on the encapsulation substrate; and
an anisotropic conductive adhesive layer having a closed-line shape, the anisotropic conductive adhesive layer being between the display panel and the encapsulation substrate to couple the display panel and the encapsulation substrate and configured to electrically connect the first pad and the second pad,
wherein the display panel comprises:
a semiconductor substrate;
a wiring layer on the semiconductor substrate and comprising the first pad; and
a light emitting element on the wiring layer.

14. The electronic device of claim 13, further comprising:
a flexible circuit board electrically connected with the timing controller,
wherein the timing controller and the flexible circuit board are electrically connected through a wiring of the encapsulation substrate.

15. The electronic device of claim 13, further comprising:
a source driver chip on the one surface of the glass substrate,
wherein the display panel further comprises a third pad and a scan line electrically connected to the third pad,
wherein the encapsulation substrate further comprises a sub-signal line on the one surface of the glass substrate and electrically connected with the source driver chip and a fourth pad electrically connected to the sub-signal line, and
wherein the third pad and the fourth pad are electrically connected through the anisotropic conductive adhesive layer.

16. The electronic device of claim 13, wherein the second pad comprises a plurality of conductive patterns and a plurality of insulating patterns,
wherein the plurality of insulating patterns and the plurality of conductive patterns are alternately stacked, and
wherein neighboring conductive patterns among the plurality of conductive patterns make contact with each other.

17. The electronic device of claim 13, wherein the second pad comprise:
a first insulating pattern overlapping an end portion of the signal line;
a first conductive pattern electrically connected to the end portion of the signal line;
a second insulating pattern overlapping the first insulating pattern and located on the first conductive pattern;
a second conductive pattern on the first conductive pattern and electrically connected to the first conductive pattern;
a third insulating pattern overlapping the second insulating pattern and located on the second conductive pattern; and
a third conductive pattern on the second conductive pattern and electrically connected to the second conductive pattern.

18. The electronic device of claim 13, wherein a maximum thickness of the second pad ranges from 4 micrometers (μm) to 7 μm.

19. The electronic device of claim 13, wherein the display panel includes a display area where the light emitting element is located and a non-display area around the display area, and
wherein a width of the non-display area is greater than or equal to 400 micrometers (μm) and less than 600 μm.

20. The electronic device of claim 13, wherein the anisotropic conductive adhesive layer comprises a photocurable resin and conductive balls mixed in the photocurable resin.
